(19) United States
(12) Patent Application Publication
(10) Pub. No.: US 2019/0187512 A1
(43) Pub. Date: Jun. 20, 2019

(54) DISPLAY UNIT AND DISPLAY APPARATUS HAVING THE SAME

(71) Applicant: SAMSUNG ELECTRONICS CO., LTD., Suwon-si, Gyeonggi-do (KR)

(72) Inventors: Byoung Jung KIM, Jeollabuk-do (KR); Byung Joo PAEK, Yongin-si (KR)

(73) Assignee: SAMSUNG ELECTRONICS CO., LTD., Suwon-si, Gyeonggi-do (KR)

(21) Appl. No.: 16/329,946

(22) PCT Filed: Aug. 21, 2017
(86) PCT No.: PCT/KR2017/009086

§ 371 Date: Mar. 1, 2019

(30) Foreign Application Priority Data
Sep. 2, 2016 (KR) 10-2016-0113338

(51) Int. Cl. G02F 1/1333; G02F 1/13357; H01L 27/32; H01L 51/52

(52) U.S. Cl. CPC G02F 1/133308; G02F 1/1336; H01L 27/32; G02F 2001/133314; G02F 2001/133317; G02F 2001/13332; H01L 51/5237

(57) ABSTRACT

The present disclosure relates to a display apparatus including a bottom chassis that is a support plate for supporting internal components. A reinforcing pattern array formed by reinforcing patterns is provided on the bottom chassis so that the bottom chassis may have a predetermined thickness or less while having increased rigidity and strength.

### CROSS-REFERENCE TO RELATED APPLICATIONS

This application is a National Phase application, under 35 U.S.C. § 371, of international application No. PCT/KR2017/009086 filed Aug. 21, 2017, which claims Convention Priority to Korean patent application No. 10-2016-0113338 filed Sep. 2, 2016, the entire disclosures of which are herein incorporated by reference as a part of this application.

### FIELD

The present disclosure relates to a display apparatus including a bottom chassis used as a support panel for supporting internal components.

### DESCRIPTION OF RELATED ART

A display apparatus is an apparatus that receives an image signal and displays an image on a screen. An example of the display apparatus is a television, a monitor, and the like.

The display apparatus includes a display panel for displaying an image, a backlight for supplying light to the display panel, and various printed circuit boards for operating the display panel.

In addition, the display apparatus includes a bottom chassis, which is a support panel for supporting the backlight or the printed circuit boards.

In recent years, the size and weight of the display panel, the backlight and the printed circuit boards have been increasing due to the trend toward larger display apparatuses, and thus it is necessary to increase the strength and rigidity of the bottom chassis, which is a support panel for supporting the display panel, the backlight and the printed circuit boards.

### SUMMARY

It is an aspect of the present disclosure to provide a display apparatus capable of increasing the strength and rigidity of a bottom chassis while keeping the bottom chassis, which is a support panel for supporting components disposed inside of the display apparatus, at a predetermined thickness or less.

In accordance with an aspect of the present disclosure, a display comprises a bottom chassis to support components inside the display, the bottom chassis includes a rear portion that is of a rectangular shape plate and side portions extending forward from outer side ends of the rear portion toward a front of the display, a reinforcing pattern array formed by a plurality of reinforcing patterns on the rear portion, and the plurality of reinforcing patterns are provided by forming a plurality of embossing portions which are raised from the bottom chassis and then pressing each of the plurality of embossing portions.

The reinforcing patterns may be each formed in a hexagon shape, and may be arranged side by side adjacent to each other.

The bottom chassis may include depressed portions formed to be recessed into the rear portion and divide the bottom chassis into a plurality of spaces.

The reinforcing patterns may be formed on both inside and outside of the depressed portions.

The reinforcing patterns may be formed only outside an area of the depressed portions.

The display may further comprise a display panel, and a backlight to supply light to the display panel, wherein the bottom chassis may support the backlight.

The backlight may include a light guide plate disposed at a rear side of the display panel, a substrate disposed at a rear side of the display panel, and a plurality of light emitting diodes disposed on the substrate, and the bottom chassis may support the light guide plate and the substrate.

The display may further comprise a display panel made of an organic light emitting diode panel, wherein the bottom chassis may support the display panel.

In accordance with another aspect of the present disclosure, a display apparatus comprises: a display panel; a support plate disposed on a rear side of the display panel and formed of a metal material to receive heat generated from the display panel; and a printed circuit board disposed on the rear of the support plate to supply an electrical signal to the display panel, wherein the support plate includes a reinforcing pattern array formed by a plurality of reinforcing patterns, and the plurality of reinforcing patterns are provided by forming a plurality of embossing portions which are raised from the support plate and then pressing each of the plurality of embossing portions.

As described above, the display apparatus according to the present disclosure can provide a bottom chassis having a predetermined thickness or less while having increased rigidity and strength by forming a reinforcing pattern array on the bottom chassis.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a perspective view of a display apparatus according to an embodiment of the present disclosure.

FIG. 2 is an exploded perspective view of a display apparatus according an embodiment of the present disclosure.

FIG. 3 is a perspective view of a bottom chassis applied to a display apparatus according to an embodiment of the present disclosure.

FIG. 4 is a cross-sectional view illustrating a process of forming embossing portions on a bottom chassis applied to a display apparatus according to an embodiment of the present disclosure.

FIG. 5 is a cross-sectional view illustrating a process of pressing embossing portions of a bottom chassis applied to a display apparatus according to an embodiment of the present disclosure.

FIG. 6 is a perspective view of a light source and a bottom chassis applied to a display apparatus according to an embodiment of the present disclosure.

FIG. 7 is a perspective view of a bottom chassis applied to a display apparatus according to an embodiment of the present disclosure.

FIG. 8 is a perspective view of a bottom chassis applied to a display apparatus according to an embodiment of the present disclosure.

FIG. 9 is an exploded perspective view of a display panel and a bottom chassis applied to a display apparatus according to an embodiment of the present disclosure.

FIG. 10 is an exploded perspective view of a backlight and a bottom chassis applied to a display apparatus according to an embodiment of the present disclosure.

### DETAILED DESCRIPTION

The embodiments described herein and the configurations shown in the drawings are only examples of preferred embodiments of the present disclosure, and various modifications may be made at the time of filing of the present disclosure to replace the embodiments and drawings of the present specification.

Like reference numbers or signs in the various figures of the present application represent parts or components that perform substantially the same functions.

The terms used herein are for the purpose of describing the embodiments and are not intended to restrict and/or to limit the present disclosure. For example, the singular expressions herein may include plural expressions, unless the context clearly dictates otherwise. The terms “comprises” and “has” are intended to indicate that there are features, numbers, steps, operations, elements, parts, or combinations thereof described in the specification, and do not exclude the presence or addition of one or more other features, numbers, steps, operations, elements, parts, or combinations thereof.

It will be understood that, although the terms first, second, etc. may be used herein to describe various components, these components should not be limited by these terms. These terms are only used to distinguish one component from another. For example, without departing from the scope of the present disclosure, the first component may be referred to as a second component, and similarly, the second component may also be referred to as a first component. The term “and/or” includes any combination of a plurality of related items or any one of a plurality of related items.

In this specification, the terms “front,” “rear,” “upper,” “lower,” “left,” and “right” are defined with reference to the drawings, and the shape and position of each component are not limited by these terms.

Hereinafter, a display apparatus according to a first embodiment of the present disclosure will be described in detail with reference to the drawings.

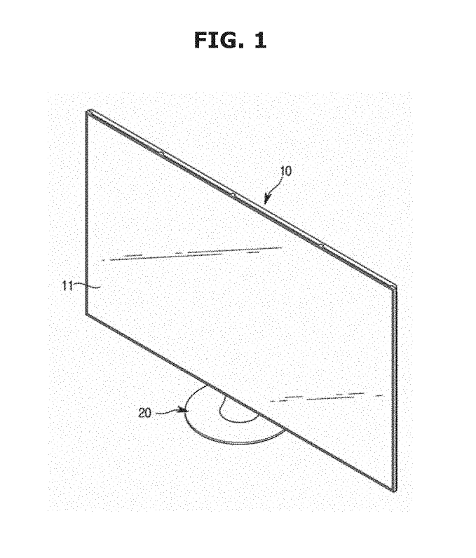

As illustrated in FIG. 1, a display apparatus according to a first embodiment of the present disclosure includes a display unit (a display) 10 for displaying an image, and a stand 20 for supporting the display unit 10 so that the display unit may be used in a standing state.

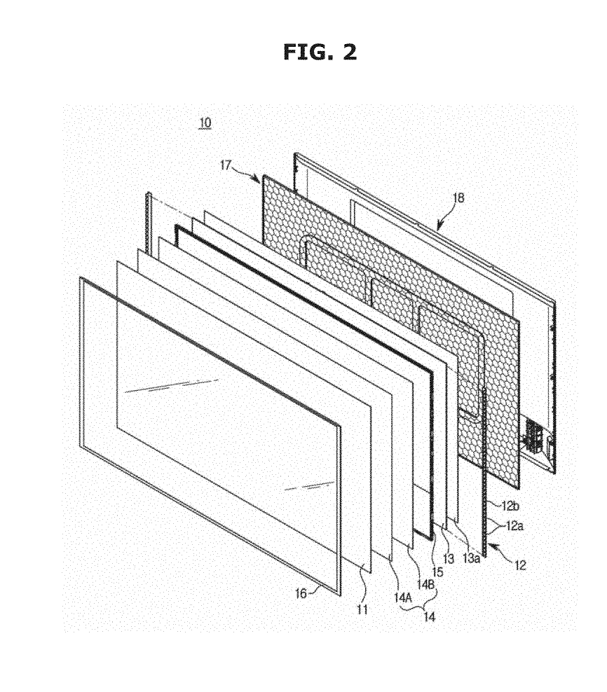

As illustrated in FIG. 2, the display unit 10 includes a display panel 11 on which an image is displayed, backlights 12 and 13 for supplying light to the display panel 11, and optical sheets 14 including 14A and 14B disposed between the display panel 11 and the backlights 12 and 13 to improve the optical characteristics of light supplied from the backlights 12 and 13.

The display unit 10 also includes a middle frame 15 for supporting the display panel 11, a top chassis 16 provided at a front side of the middle frame 15 to maintain a state in which the display panel 11 is supported by the middle frame 15, a bottom chassis 17 provided at a rear side of the middle frame 15 to accommodate the backlights 12 and 13, and a case 18 which covers a rear surface of the bottom chassis 17 and forms a rear surface of the display unit 10.

In addition, although not shown in the drawings, various printed circuit boards for driving the display unit 10 are mounted on the rear surface of the bottom chassis 17, and the case 18 serves to cover these printed circuit boards. The printed circuit boards include a power board for power supply, a panel drive board for transmitting power to the display panel 11, a timing control board for transmitting an image signal to the display panel 11, a signal processing board for processing image signals and sound signals, and the like.

The display panel 11 is formed of a liquid crystal panel and receives light from the backlights 12 and 13 to display an image.

The backlights 12 and 13 include the light guide plate 13 formed in a rectangular flat plate shape so as to correspond to the display panel 11, and a pair of the light sources 12 arranged so as to correspond to opposite side surfaces of the light guide plate 13 to irradiate light toward the opposite side surfaces of the light guide plate 13.

The light guide plate 13 is made of a transparent resin material so as to guide light, and a white reflective sheet 13a for reflecting light disposed on a rear surface of the light guide plate 13. Accordingly, the light emitted from the light source 12 is incident on the inner side of the light guide plate 13 through the opposite side surfaces of the light guide plate 13 and is reflected by the reflective sheet 13a, and then exits through a front surface of the light guide plate 13.

Each of the light sources 12 includes a plurality of light emitting diodes 12a, and a rectangular bar-shaped substrate 12b in which the light emitting diodes 12a are arranged in a row. The substrates 12b are vertically arranged to correspond to the opposite side surfaces of the light guide plate 13, and the light emitting diodes 12a are vertically disposed on the substrate 12b so as to face one surface of the light guide plate 13.

The optical sheets 14 which includes the dual brightness enhancement film (DBEF) sheet 14A which is a high-brightness prism sheet, and the diffuser sheet 14B for diffusing incident light.

The middle frame 15 is formed in a substantially rectangular ring shape to support outer sides of the rear surface of the display panel 11.

The top chassis 16 is formed in a substantially rectangular ring shape and is coupled to a front side of the middle frame 15 to support front outer sides of the display panel 11, so that the display panel 11 is maintained in a state of being mounted on the middle frame 15.

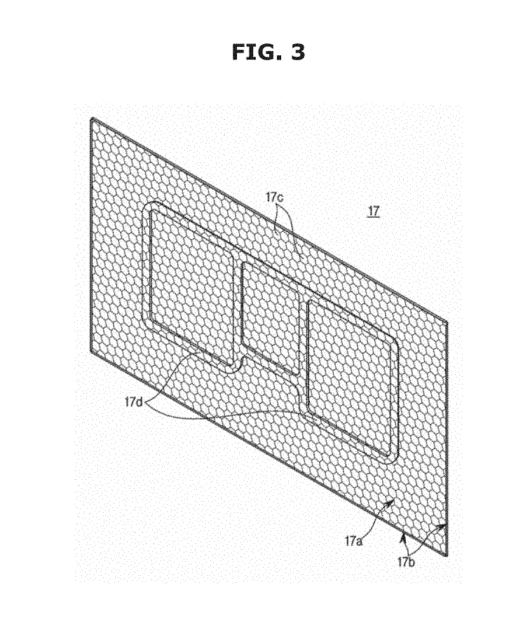

The bottom chassis 17 is formed of a metal material so that heat generated from the light sources 12, 13, the printed circuit boards, and the like may easily be dissipated. As illustrated in FIG. 3, the bottom chassis 17 includes a rear portion 17a formed in a substantially rectangular plate shape, and side portions 17b extending forward from the four ends of the rear portion 17a to be coupled to the middle frame 15. The bottom chassis 17 is formed to have a predetermined strength or higher and function as a support plate for supporting the backlights 12 and 13. Since the bottom chassis 17 is formed of a metal material as described above, the bottom chassis 17 receives heat generated from the display panel 11, the backlights 12 and 13, or the printed circuit boards to diffuse through a surface thereof, and thus the bottom chassis 17 also serves as a heat radiating plate that allows heat to be radiated into the air more quickly.

The bottom chassis 17 further includes a reinforcing pattern array formed by a plurality of reinforcing patterns 17c that are provided in the rear portion 17a of the bottom chassis 17 to increase the strength and rigidity of the bottom chassis 17, and depressed portions 17d formed by recessing the rear portion 17a of the bottom chassis 17 rearward.

The reinforcing patterns 17c are formed such that an outer line thereof has a relatively high density as compared with an inner portion thereof, thereby enhancing the strength and rigidity of the bottom chassis 17. In the present embodiment, the reinforcing patterns 17c are each formed in a regular hexagonal shape and are arranged side by side vertically and horizontally.

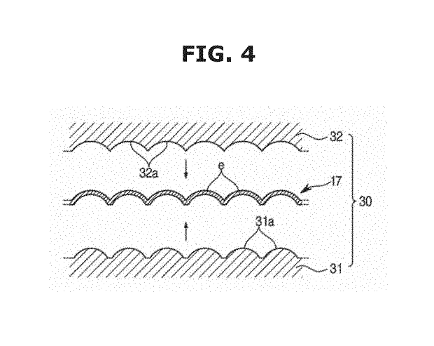

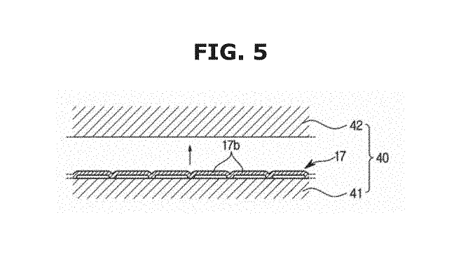

The reinforcing pattern array is formed by a first press mold 30 illustrated in FIG. 4 and a second press mold 40 illustrated in FIG. 5.

The first press mold 30 is composed of a first lower mold 31 on which a plate to be processed is placed on an upper surface thereof, and a first upper mold 32 provided so as to be movable vertically above the first lower mold 31.

The first lower mold 31 includes protrusions 31a provided on the upper surface thereof, and the first upper mold 32 includes grooves 32a formed at positions corresponding to the protrusions 31a, on a lower surface of the first upper mold 32.

Accordingly, a plurality of embossing portions (e) are formed by placing the bottom chassis 17 on the first lower mold 31 and moving the first upper mold 32 downward to press the bottom chassis 17, and an embossing array is formed by the plurality of embossing portions (e).

The plurality of reinforcing patterns 17c are formed by pressing the embossing portions (e) formed on the bottom chassis 17 through the second press mold 40 as illustrated in FIG. 5, respectively, and the reinforcing pattern array is formed by the plurality of reinforcing patterns 17c.

The second press mold 40 is composed of a second lower mold 41 on which the bottom chassis 17 formed with the embossing portions (e) is placed on an upper surface thereof, and a second upper mold 42 provided so as to be movable vertically above the second lower mold 41. In this case, the upper surface of the second lower mold 41 and a lower surface of the second upper mold 42 are formed as flat surfaces so as to be able to deform the embossing portions (e) flatly.

When the embossing portions (e) are deformed flatly by pressing the respective embossing portions (e) through the second press mold 40 as described above, the plurality of reinforcing patterns 17c are formed on the bottom chassis 17, and the plurality of reinforcing patterns 17c form the reinforcing pattern array. Thus, the strength and rigidity of the bottom chassis 17 are increased by the reinforcing pattern array.

More specifically, when the embossing portions (e) are formed on the bottom chassis 17 through the first press mold 30, the thickness of the portion where the embossing portions (e) are formed becomes relatively thinner than the original thickness of the plate forming the bottom chassis 17.

In this state, the bottom chassis 17 on which the embossing portions (e) are formed is placed on the second lower mold 41, and the second upper mold 42 is moved downward to press the embossing portions (e) to deform the embossing portions (e) into a flat shape.

While the inner portion of each of the embossing portions (e) is easily deformed by the second upper mold 42 because the inner portion of each of the embossing portions (e) is spaced apart from the upper surface of the second lower mold 41, the outer line of each of the embossing portions (e) and the portion adjacent to the outer line are not easily deformed because they are directly or indirectly supported by the second lower mold 41. Accordingly, after the inner portion of each of the embossing portions (e) has been deformed by the force applied by the second upper mold 42, most of the force exerted by the second upper mold 42 is used to press the outer line of each of the embossing portions (e) and the portion adjacent to the outer line.

Thus, the outline of each of the reinforcing patterns 17c manufactured through the above process has a higher density than the inner portion thereof, contributing to an increase in the strength and rigidity of the bottom chassis 17.

In this embodiment, the reinforcing patterns 17c forming the reinforcing pattern array are formed in such a manner that the outline lines of the reinforcing patterns 17c are formed in a regular hexagon, and are connected to each other vertically and horizontally to form a substantially honeycomb-like shape.

The depressed portions 17d, which serve to divide the rear portion 17a of the bottom chassis 17 into a plurality of spaces, are formed in a substantially rectangular ring shape at a center portion of the rear portion 17a of the bottom chassis 17. In this embodiment, three of the depressed portions 17d in a rectangular shape are formed to be connected to each other, and the printed circuit boards are disposed inside the depressed portions 17d. That is, the depressed portions 17d also serve to partition the arrangement region of the above-described printed circuit boards.

The depressed portions 17d serve to increase the strength of the central portion of the rear portion 17a of the bottom chassis 17, and the effect of increasing the strength by the depressed portions 17d is proportional to the height of the depressed portions 17d. Therefore, in order to obtain a sufficient strength increasing effect by the depressed portions 17d, the height of the depressed portions 17d must be made higher than a predetermined height.

However, as described above, since the reinforcing pattern array is formed on the rear portion 17a of the bottom chassis 17 to increase the strength and rigidity of the bottom chassis 17, it is possible to form the depressed portions 17d relatively lower than the conventional ones instead of forming the reinforcing patterns 17c.

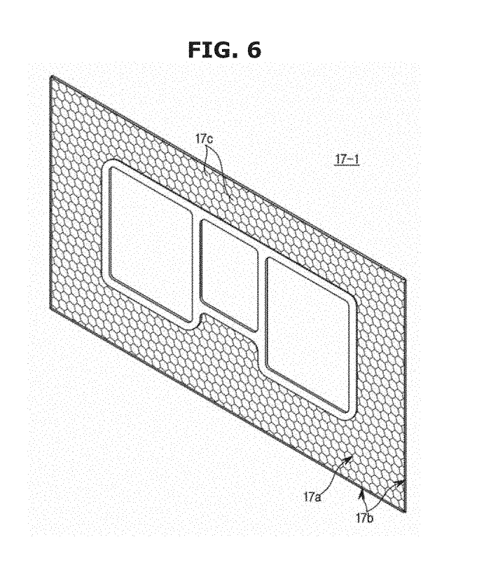

In this embodiment, the reinforcing pattern array is formed entirely on the bottom chassis 17, but the present disclosure is not limited thereto. For example, as illustrated in FIG. 6, a display apparatus according to a second embodiment of the present disclosure may include a bottom chassis 17-1 provided such that the reinforcing patterns 17c are not formed on the depressed portions 17d and the regions inside the depressed portions 17d where the sufficient strength is ensured by the depressed portions 17d and such that the reinforcing pattern array formed by the reinforcing patterns 17c is limitedly formed only on the outer side of the depressed portions 17d.

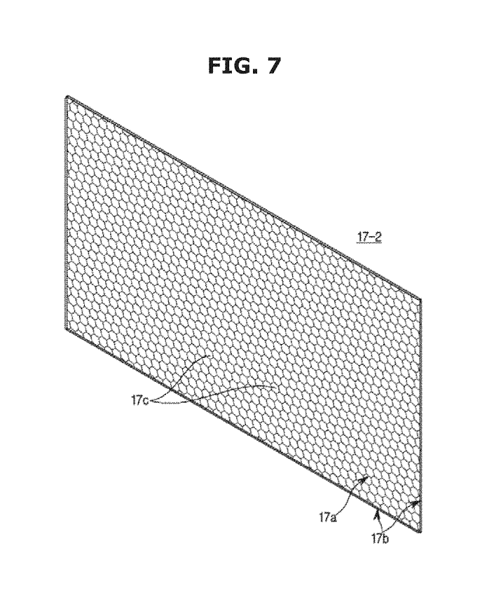

Also, as illustrated in FIG. 7, in a case where a bottom chassis 17-2 of a display apparatus according to a third embodiment of the present disclosure is applied to a display apparatus having a relatively small size, the bottom chassis 17-2 may have sufficient strength and rigidity even if only the reinforcing pattern array by the reinforcing patterns 17c is formed on the bottom chassis 17-2 without the depressed portions 17d.

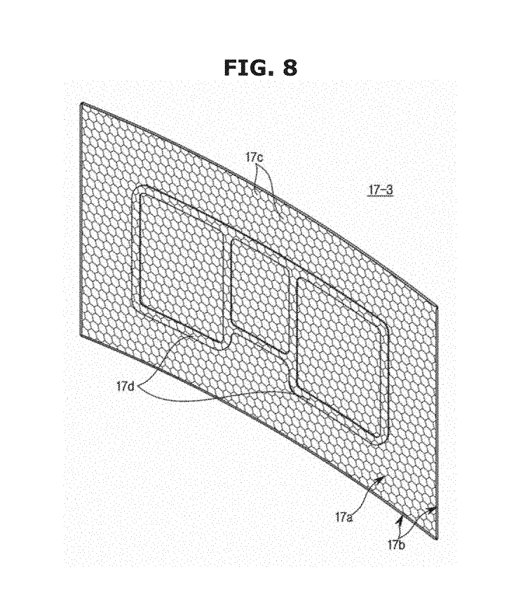

Although the bottom chassis 17 according to the display apparatus of the first embodiment is formed in a substantially rectangular flat plate shape, the present disclosure is not limited thereto. For example, as illustrated in FIG. 8, in a case where a bottom chassis 17-3 of a display apparatus according to a fourth embodiment of the present disclosure is applied to a curved display apparatus, the bottom chassis 17-3 is formed such that opposite side ends of the bottom chassis 17-3 are bent so as to protrude forward as compared with a center portion of the bottom chassis 17-3. The reinforcing patterns 17c of the present disclosure may also be formed on the curved bottom chassis 17-3 to increase the strength and rigidity of the curved bottom chassis 17-3.

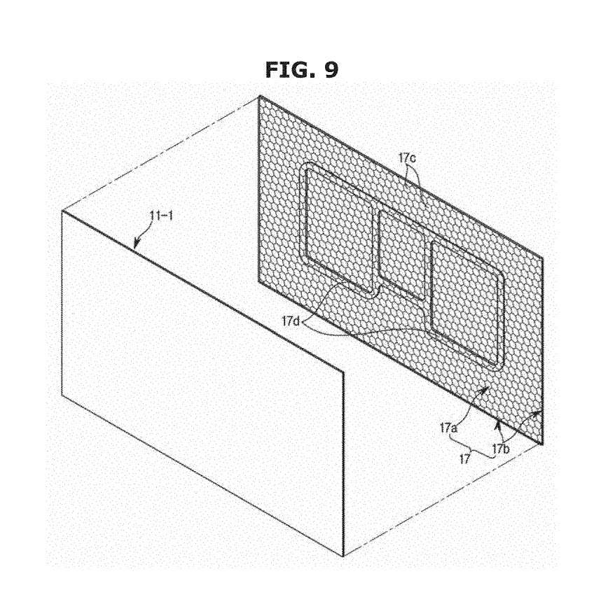

Since the display apparatus according to the first embodiment includes the backlights 12 and 13 to supply light to the display panel 11 made of a liquid crystal panel, the bottom chassis 17, which is a support plate, supports the backlights 12 and 13, but the present disclosure is not limited thereto. For example, as illustrated in FIG. 9, in a case where a display panel 11-1 of a display apparatus according to a fifth embodiment of the present disclosure is made of an organic light emitting diode panel, the backlights 12 and 13 are not required. Therefore, it is also possible to attach the display panel 11-1 to the bottom chassis 17, which is a support plate, so that the bottom chassis 17 may directly supports the display panel 11-1.

The display apparatus according to the first embodiment includes the backlights 12 and 13 of an edge type including the light guide plate 13 and the light sources 12 arranged to face the opposite side surfaces of the light guide plate 13, and the bottom chassis 17, which is a support plate, supports the light guide plate 13, but the present disclosure is not limited thereto.

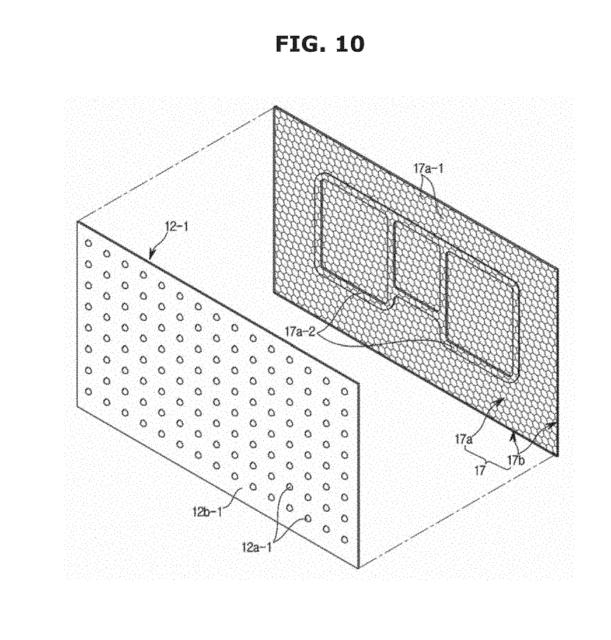

That is, as illustrated in FIG. 10, in a case where a display apparatus according to a sixth embodiment of the present disclosure includes a direct-type backlight 12-1 for supplying light to the display panel 11 and the backlight 12-1 includes a substrate 12b-2 disposed to be spaced apart from the rear of the display panel 11 and light-emitting diodes 12a-1 arranged on the substrate 12b-2, it is also possible for the bottom chassis 17, which is a support plate, to support a substrate 12b-1 of the backlight 12-1.

In the above embodiments, the reinforcing patterns 17c are illustrated as being formed in a regular hexagon, but this is only an example. That is, the reinforcing patterns 17c may be formed in various shapes such as polygons other than a regular hexagon, a circle, an ellipse, and combinations thereof.

Also, in the above embodiments, it has been mainly described that the bottom chassis 17 serves as a support plate for supporting the components of the display unit 10, but the present disclosure is not limited thereto. For example, the bottom chassis 17 may serve to form a space for accommodating the display panel 11 or the backlights 12 and 13, and may also serve as a radiating plate to help release heat generated in the printed circuit boards.

Although a few embodiments of the present disclosure have been shown and described, it would be appreciated by those skilled in the art that changes may be made in these embodiments without departing from the principles and spirit of the present disclosure in the scope of which is defined in the claims and their equivalents.

1. A display, comprising:
a bottom chassis to support components inside the display, the bottom chassis including:
a rear portion that is of a rectangular shape plate,
side portions extending forward from outer side ends of the rear portion toward a front of the display,
a reinforcing pattern array formed by a plurality of reinforcing patterns on the rear portion, and
wherein the plurality of reinforcing patterns are provided by forming a plurality of embossing portions which are raised from the bottom chassis and then pressing each of the plurality of embossing portions.

2. The display according to claim 1, wherein:
the reinforcing patterns are each formed in a hexagon shape, and are arranged side by side adjacent to each other.

3. The display according to claim 1, wherein:
the bottom chassis includes depressed portions formed to be recessed into the rear portion and divide the bottom chassis into a plurality of spaces.

4. The display according to claim 3, wherein:
the reinforcing patterns are formed on both inside and outside of the depressed portions.

5. The display according to claim 3, wherein:
the reinforcing patterns are formed only outside an area of the depressed portions.

6. The display according to claim 1, further comprising:
a display panel, and a backlight to supply light to the display panel,
wherein the bottom chassis supports the backlight.

7. The display according to claim 6, wherein the backlight includes:
a light guide plate disposed at a rear side of the display panel,
a substrate disposed at a rear side of the display panel, and
a plurality of light emitting diodes disposed on the substrate, and
wherein the bottom chassis supports the light guide plate and the substrate.

8. The display according to claim 1, further comprising:
a display panel made of an organic light emitting diode panel,
wherein the bottom chassis supports the display panel.

9. A display apparatus comprising:
a display panel;
a support plate disposed on a rear side of the display panel, the support plate being formed of a metal material to receive heat generated from the display panel including a printed circuit board disposed at a rear of the support plate to supply an electrical signal to the display panel; and
wherein the support plate includes a reinforcing pattern array formed by a plurality of reinforcing patterns, and
the plurality of reinforcing patterns are provided by forming a plurality of embossing portions which are raised from the support plate and then pressing each of the plurality of embossing portions.

10. The display apparatus according to claim 9, wherein:
the reinforcing patterns are each formed in a hexagon shape, and the reinforcing pattern array is provided by repeatedly forming the reinforcing patterns in the hexagonal shape adjacent to each other.

11. The display apparatus according to claim 9, wherein:
the display panel includes an organic light emitting diode panel, and
the display panel is attached to the support plate.

12. The display apparatus according to claim 9, wherein:
the display panel includes a liquid crystal panel,
the display apparatus further includes a backlight disposed on the rear side of the display panel, and
the support plate supports the backlight.
